(19) United States
(12) Patent Application Publication
(10) Pub. No.: US 2003/0054589 A1
(43) Pub. Date: Mar. 20, 2003

(54) Method of improving mount assembly in a multilayer PCB's

(75) Inventors: Yoshinari Matsuda, San Diego, CA (US); Ikuo Jimmy Sanwo, San Marcos, CA (US); Mahyer Nejat, San Diego, CA (US)

Correspondence Address: Intellectual Property Department, Sony Electronics Inc., 16450 West Bernardo Drive, MZ 7190, San Diego, CA, 92127-1898, US

(73) Assignee: Sony Corporation

(21) Appl. No.: 10/051,248

(22) Filed: Jan. 18, 2002

Related U.S. Application Data
(60) Provisional application No. 60/323,762, filed on Sep. 17, 2001.

(51) Int. Cl. H01L 21/44; H01L 21/48; H05K 1/00; H01L 23/48

(52) U.S. Cl. 438/108; 257/693; 361/777

(57) ABSTRACT

The invention is directed to a chip size package (“CSP”) configuration and method for arranging a CSP configuration which is simple to manufacture, and less costly. The invention includes a structure for a printed circuit board (“PCB”), having at least a single pad for a chip size package (“CSP”) which is square shape. The CSP pad then is rotated 45 degrees in a clockwise or counter clockwise direction from a perpendicular so as to form a diamond shape. Also included is at least a via having a circle shape and wherein the distance between an inner side of the rotated CSP pad, where the inner side is the side closest to the via, and the outer edge of the via is at least 0.1 mm.

### CROSS REFERENCE TO RELATED DOCUMENTS

This application is related to Provisional Patent Application Serial No. 60/323,762, by Matsuda, et al., filed Sep. 17, 2001 and entitled METHOD OF IMPROVING MOUNT ASSEMBLY IN MULTILAYER PWB'S WHICH UTILIZE SUPER FINE PITCH (0.8) PACKAGE SUCH AS BGA AND CSP, which is hereby incorporated herein by reference.

### COPYRIGHT NOTICE

A portion of the disclosure of this patent document contains material which is subject to copyright protection. The copyright owner has no objection to the facsimile reproduction of the patent document or the patent disclosure, as it appears in the Patent and Trademark Office patent file or records, but otherwise reserves all copyright rights whatsoever.

1. Field of the Invention

This invention relates to mounting of electronic modules on an inventive configuration for chip scale packages CSP, where a diamond shape structure is being used. More particularly, this invention relates to better miniaturizing of CSP's for manufacturing having an improved package interconnection between structures for providing better reliability and mechanical strength on the solder joints

2. Background of the Invention

Components of module packages using a column grid array (CGA), ball grid array (BGA) or chip scale packages (CSP) use various processing technologies to achieve higher pitch densities. These higher pitches densities are in the ranges from 0.050(in) (1.27 mm) to less than 0.025(in) (0.63 mm). However, for interconnection of various modules having pitches densities of less than 0.1 mm, the circuit board fabrication is both difficult and expensive. There is also a great likelihood of performance failure and accordingly there is a need to have better module fabrication processes to overcome this problem. Moreover, these higher pitch densities are necessary in the fabrication of circuit boards which are used in many kinds of modules which used in digital circuits for DTV applications, digital cell phones, digital cameras, and lap top computers using LSI technology with both ball grid array DGB packages and chip size packages CSPs.

As the performance requirements of these products are increased, the size of the die packaging is decreased proportionately, and hence the numbers of I/O pin density of the integrated circuit (IC) packages and other interfaces will have to be increased. As a result, IC chip engineers have developed a wide variety of package designs to maximize I/O pin density and reduce overall package size. One example of a package design that has a relatively high I/O density is a chip scale package. The typical chip scale package includes an array of pads to provide interconnection between the IC devices within the die and other electrical components of IC devices external to the die. An array configuration allows the engineer to utilize the package area for I/O pad placement as opposed to other package design such as surface mount packages, which typically provide I/O pins only around the package perforate. The typical CSP has an overall package dimensions substantially equal to that of a silicon active device or die that is enclosed within the package. Moreover, in the past few years the pitch to pitch distances have been reduced in chip scale packages from 1.27 mm to 1.00 mm, and now are currently 0.8 mm pitches densities. Another significant challenge with the chip scale package design is the processing of attaching the pads onto individual sites. In many cases it is difficult to meet the high tolerance requirements for CSP applications if a die is not adequately isolated from other parts of the package. In some instances this improper die isolation can result in premature failure of the device because the solder joints fatigue due to excess stresses between an assembled die and its substrate. Also, in the case of chip scale packages (CSP) with 0.8 mm pitch when attaching devices onto a PCB, there is an increase in solder bridges, electrical shorts, and other possible problems associated with the soldering process during manufacturing.

FIG. 1 shows a conventional kind of DRAM CSP package with a 0.8 mm pitch. Here the VIA 60 has a pad diameter of approximately 0.55 mm and a solder resist diameter (SR) of 0.45. Further, each of the other CSP pads has a pad diameter of 0.4 mm and a solder resist diameter (SR) of 0.3 mm.

Once the distance of the solder resist diameters are included in the space between the VIA and CSP pads, the space between is reduced to 0.191 mm (40), or less than a 0.200 mm tolerance. Generally, when the tolerance fall below the 0.2 mm threshold, there is a great increase in manufacturing defects such as micro solder bridge defects and other solder defects resulting in more solder wicks needed to be manufactured in each of CSP VIA holes.

Another associated problem is the distance between the VIA pads and the CSP pads is also reduced to a space of only 0.096 mm (20). It, again, is costly to manufacture a PCB with a 0.096 mm distance between the VIA and the pads because such high tolerances are well above normal manufacturing processes thresholds and often cause manufacturing problems.

The aforementioned problems all contribute to an increase in production costs or a decrease in production yields. Consequently, there is a need for an improved IC package that provides a solution to the aforementioned problems and provides a plurality of pads. Additionally, there is a need for a new method for making such an improved package.

### SUMMARY OF THE INVENTION

To achieve the foregoing and other objects according to the purpose of the present invention a CSP configuration is disclosed. The CSP configuration has a plurality of pads for surface mountings of circuit devices. The placement of the pads by increasing the pitch distance between the pads enables the mounting of devices on the pads on a multilayer PCB in a manner to prevent manufacturing defects.

In one embodiment of the present invention is disclosed a chip size package (“CSP”) configuration, having a CSP pad with a diamond shape composed of four identical sides and a VIA pad having a circular shape. Further, a side of the CSP pad nearest to the VIA pad is a distance of at least of 0.1 mm from the CSP pad side where the distance is measured from the side of the CSP pad to an outer edge of the circular shape of the VIA pad..

In another embodiment of the present invention is disclosed a structure for a printed circuit board (“PCB”), including at least a single pad for a chip size package (“CSP”) having a square shape. The CSP pad is rotated 45 degrees in a clockwise or counter clockwise direction from a perpendicular so as to form a diamond shape. Also, there is included at least a VIA having a circle shape and where the distance between an inner side of the rotated CSP pad, where the inner side is the side closest to the VIA, and the outer edge of the VIA is at least 0.1 mm.

In yet another embodiment of the present invention is disclosed a method for arranging a chip size package, including rotating at least a square shaped CSP pad so as to form a diamond shape. Further, placing a via adjacent to the CSP pad such that a side of the CSP pad closest to the via is at least 0.1 mm.

The features of the invention believed to be novel are set forth with particularity in the appended claims. The invention itself however, both as to organization and method of operation, together with further objects and advantages thereof, may be best understood by reference to the following description taken in conjunction with the accompanying drawing.

### BRIEF DESCRIPTION OF THE DRAWING

The following detailed description, given by way of example, and not intended to limit the present invention solely thereto, will best be understood in conjunction with the accompanying drawings in which corresponding reference numerals refer to similar elements in which:

FIG. 1 is a diagram of a conventional CSP package; and

FIG. 2 is a diagram of a CSP package in accordance with an embodiment of the present invention.

### DETAILED DESCRIPTION OF THE INVENTION

In general, the present invention relates to wafer chip level CSP packages that include CSP pads. Each CSP pad is placed above a resilient protective layer. The resilient protective layer acts as a cushion between the underlying layers and the contact of the IC package, where the IC package is mounted on the external substrate. Although the present invention is described as being implemented in surface mount type wafer level CSP's of course, it should be well understood to those skilled in the art that the present invention is not limited to wafer level CSP's; that is, the present invention may be implemented in any kind of IC package that requires a less than 0.2 mm space between the VIA and the CSP pads.

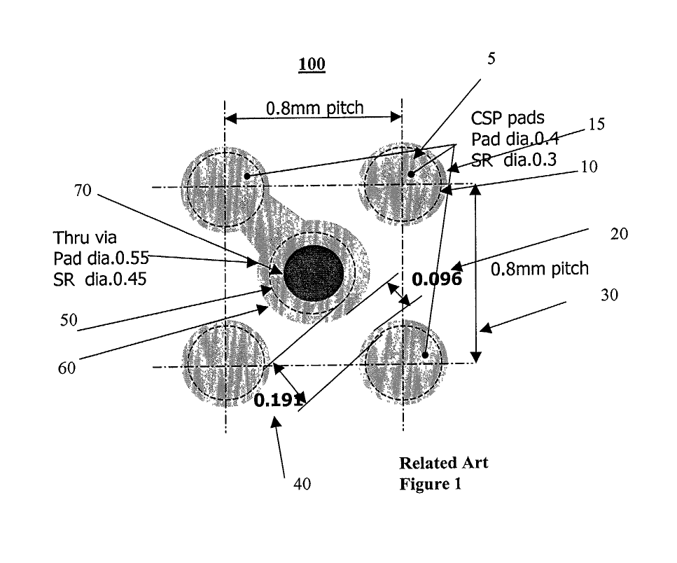

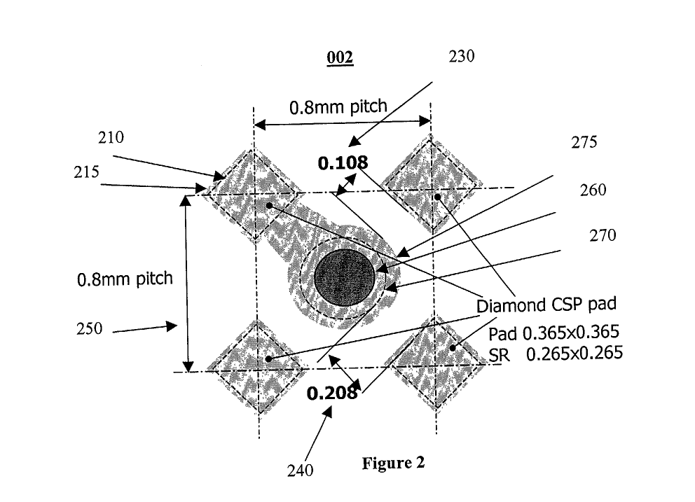

FIG. 2 shows four diamond shaped pads, each of these diamond shaped pads have a 0.365×0.365 mm dimensions. Each diamond shaped pad 210 is oriented such that the center of the diamond shaped pad is at the same point as the center of the circular pads of FIG. 1. However, each pad which is square in shape is rotated so that a particular side of the square is at a 45° angle from a perpendicular axis and hence each pad appears diamond shape. By rotating each pad 45° degrees the distance from the inner sides of the pad to the VIA 260 is increased to 0.108 mm. That is, from an outer most edge of the VIA 260 to the nearest point on the pad 210 is at a midpoint on the inner side which is at least 0.108. Further the distance form the solder resist diameter of the VIA 270 to the solder resist edge of the pad 210 is increased to be greater than 0.2 mm; the distance is measured to be approximately 0.208 mm (240). However, even though this distance 240 is now the least distance from the VIA 260 to the pad 210, this distance is greater than having the pad in any other orientation. Accordingly, the distance between the VIA and the pad is increased by the turning and re-orientation of the pad by 45°, and also the shape of the pad is now positioned to appear diamond shape with the nearest point to the VIA pad being the midpoint of the diamond inner side of the pad 210.

As shown in FIG. 2, there are four pads 210 and a VIA 260. The pads are rotated to be diamond shaped and have the same surface area as circular pads with a 0.4 mm diameter. The pitch between adjacent pads is 0.8 mm pitch or the same pitch as in the conventional circular pad arrangement of FIG. 1. Moreover, the rotated pads provide the level of same reliability and mechanical strength on the solder joints as the circular pads. Further, the solder resist opening gaps between the VIA and CSP pads is now 0.208 mm, an 8.9% increase over the conventional circular pad arrangement of FIG. 1. With this design, in manufacturing PCB's with components and when having a greater than 0.2 mm tolerance, there is a reduced likelihood to have defects as the distance between the VIA and pads is sufficiently great to prevent soldering bridges from occurring. If the distance of a copper gap is viewed, the space between the VIA and pads is now 0.108 mm or a 12.5% increase over conventional arrangements. Also, the etching processes during manufacturing are more stable and there is a reduction in micro soldering ridges on the assembly processes. Further, these pads can be easily utilized in current PCB and soldering assembly processes; making conversion to the new pad design very simple.

Additionally, this diamond shaped pad arrangement can eliminate or at the very least reduce the need for alternative approaches such as Blind VIA hole (BVH) technology, which are currently needed in the 0.8 mm pitch CSP design. Hence, using the pads and also using only through holes enable PCB costs to be dramatically reduced.

Thus it is apparent that in accordance with the present invention, an apparatus that fully satisfies the objectives, aims and advantages is set forth above. While the invention has been described in conjunction with specific embodiments, it is evident that many alternatives, modifications, permutations and variations will become apparent to those skilled in the art in light of the foregoing description. Accordingly, it is intended that the present invention embrace all such alternatives, modifications and variations as fall within the scope of the appended claims.

What is claimed is:

1. A chip size package (“CSP”) configuration, comprising:
a CSP pad having a diamond shape composed of four identical sides;
a via pad having a circular shape;
wherein the side of said CSP pad nearest to said via pad being a distance at least of 0.1 mm from the CSP pad.side wherein said distance being from the side of the CSP pad to an outer edge of the circular shape of the via pad..

2. The CSP configuration of claim 1, wherein said via pad having a diameter of approximately 0.55 mm.

3. The CSP configuration of claim 1, wherein said via pad having a solder resist diameter of approximately 0.45 mm.

4. The CSP configuration of claim 1, wherein each side of the diamond shape of the CSP pad being approximately 0.365 mm in length.

5. The CSP configuration of claim 1, wherein each side of the diamond shape of the CSP pad having a solder resist side being approximately 0.265 mm in length.

6. The CSP configuration of claim 1, wherein said CSP pad having an approximate surface area equivalent to a circular pad having a solder resist diameter of 0.300 mm.

7. The CSP configuration of claim 1, wherein said via pad having a solder resist diameter of approximately 0.45 mm and each side of the diamond shape of the CSP pad having a solder resist side being approximately 0.265 mm wherein a nearest distance from the via pad to the solder resist side of the CSP pad being at least of 0.2 mm.

8. The CSP configuration of claim 7, wherein said nearest distance being sufficient to prevent bridge soldering defects and electrical shorts..

9. The CSP configuration of claim 1, wherein said distance being sufficient to prevent bridge soldering defects and electrical shorts.

10. The CSP configuration of claim 1, further comprising:
multiple CSP pads having a diamond shape composed of four identical sides surrounding said via wherein the distance of each of the sides of the CSP pads is at least 0.2 mm.

11. The CSP configuration of claim 10, wherein a pitch distance between each of the CSP pads being approximately 0.8 mm wherein the pitch distance being a distance from a center of a CSP pad to the center of an adjacent CSP pad.

12. The CSP configuration of claim 11, wherein said pitch distance not exceeding much 0.8 mm.

13. A structure for a printed circuit board (“PCB”), comprising:
at least a pad for a chip size package (“CSP”) having a square shape, the CSP pad being rotated 45 degrees in a clockwise or counter clockwise direction from a perpendicular so as to form a diamond shape;
at least a via being a circle shape;
wherein the distance between an inner side of the rotated CSP pad, wherein the inner side being the side closest to the via, and the outer edge of the via being at least 0.1 mm.

14. The structure of claim 13, wherein the via having a diameter in the vicinity of 0.55 mm.

15. The structure of claim 13, wherein the via having a diameter of no more than 0.6 mm.

16. The structure of claim 13, wherein the via having a solder resist diameter in the vicinity of 0.45 mm.

17. The structure of claim 13, wherein the via having a solder resist diameter of no more than 0.5 mm.

18. The structure of claim 13, wherein the CSP pad having a surface area nearly equal to circular pad of solder resist diameter in the vicinity of 0.3 mm.

19. The structure of claim 13, wherein said via having a solder resist diameter in the vicinity of 0.45 mm and each side of the diamond shape of the CSP pad having a solder resist side length in the vicinity of 0.26 mm wherein the distance from the closest solder resist side to the via being at least 0.2 mm.

20. The structure of claim 19, wherein said distance being large enough to prevent bridge soldering defects and electrical shorts.

21. The structure of claim 13, wherein said distance being large enough to prevent bridge soldering defects and electrical shorts.

22. The structure of claim 13, wherein a pitch distance between a CSP pad and an adjacent CSP pad being in the vicinity of 0.8 mm.

23. A method for arranging a chip size package, comprising:
rotating at least a square shaped CSP pad so as to form a diamond shape;
placing a via adjacent to said CSP pad such that a side of the CSP pad closest to said via being at least 0.1 mm.

24. The method of claim 23, wherein said via having a diameter in the vicinity of 0.55 mm.

25. The method of claim 23, wherein a length of said side of the CSP pad being in the vicinity of 0.365 mm.

26. The method of claim 23, wherein the square shaped CSP pads being rotated about 45 degrees from a perpendicular in a clockwise or counterclockwise direction.

27. The method of claim 23, wherein a distance of a center of the square shaped CSP pad and an adjacent square shape CSP be in the vicinity of 0.8 mm.

28. A structure for a printed circuit board (“PCB”), comprising:
at least a pad means for a chip size package (“CSP”) having a square shape, the pad means being rotated 45 degrees in a clockwise or counter clockwise direction from a perpendicular so as to form a diamond shape;
at least a via being a circle shape;
wherein the distance between an inner side of the rotated pad means, wherein the inner side being the side closest to the via, and the outer edge of the via being at least 0.1 mm.
